(19) United States
(12) Patent Application Publication
(10) Pub. No.: US 2016/0240424 A1
(43) Pub. Date: Aug. 18, 2016

(54) CHUCK TABLE OF PROCESSING APPARATUS

(71) Applicant: DISCO CORPORATION, Tokyo (JP)

(72) Inventors: Masahiro Tsukamoto, Tokyo (JP); Ken Togashi, Tokyo (JP)

(21) Appl. No.: 15/042,443

(22) Filed: Feb. 12, 2016

(30) Foreign Application Priority Data
Feb. 12, 2015 (JP) 2015-025240

(51) Int. Cl. H01L 21/687; H01L 21/683

(52) U.S. Cl. CPC H01L 21/68735; H01L 21/6836; H01L 21/68721; H01L 21/6838; H01L 2221/68327

(57) ABSTRACT

A chuck table in processing apparatus holds a frame unit in which a wafer is fixed to an opening of a ring-shaped frame with an intermediary of adhesive tape by sucking an exposed surface of the wafer to a holding surface. The chuck table includes a circular region that forms the holding surface in which plural suction holes communicating with a suction source are formed, and a ring-shaped circumferential region that surrounds the circular region. The diameter of the circular region is smaller than the diameter of the wafer. The circumferential region is formed to include a diameter larger than the diameter of the wafer and smaller than the inner diameter of the ring-shaped frame, and a recess that suppresses the sticking of the adhesive tape is formed in an upper surface of the circumferential region that gets contact with the adhesive tape.

### BACKGROUND OF THE INVENTION

1. Field of the Invention

The present invention relates to a chuck table of processing apparatus such as laser processing apparatuses and cutting apparatuses.

2. Description of the Related Art

For optical device wafers or the like in which an light emitting layer is formed over a semiconductor wafer or an epitaxial substrate of sapphire, SiC, GaN, or the like, the following processing method has begun to be used in recent years. Specifically, in this method, the wafer is irradiated with a laser beam having such a wavelength as to be transmitted through the wafer, with the light focus point positioned inside the wafer, to form a modified layer inside the wafer. Subsequently, an external force is given to the wafer and the wafer is divided into individual device chips by utilizing the modified layer as the origin of fracturing (refer to Japanese Patent No. 3408805 for example).

This processing method is conditioned on that what attenuates the energy of the laser beam (e.g. material to form various kinds of patterns forming devices) is not formed on the side of the surface irradiated with the laser beam. Therefore, for a wafer having the front surface on which plural devices are formed, irradiating the wafer with a laser beam from the back surface side, on which devices do not exist, to form a modified layer inside the wafer is generally carried out.

At this time, also in the case in which the wafer cannot be irradiated with the laser beam from the front surface side of the wafer, on which the devices are formed, the following method is often employed similarly to one used in normal processing. Specifically, the back surface of the wafer is stuck to adhesive tape and a frame unit that supports the wafer by a ring-shaped frame with the intermediary of the adhesive tape is formed. Then, the front surface of the wafer is placed on a holding surface of a chuck table and the wafer is irradiated with the laser beam through the adhesive tape.

### SUMMARY OF THE INVENTION

However, in this processing method, the adhesive layer of the adhesive tape overlaps with the chuck table on the outside of the circumference of the wafer. Thus, there is a problem that the adhesive layer exposed at the periphery of the wafer is stuck to the circumferential part of the chuck table and a conveyance error after processing is caused. As a countermeasure against this problem, a method in which a porous sheet is placed on the holding surface of the chuck table to cover the holding surface has also been proposed. However, this method involves a problem that the chuck table needs to be changed to have special specifications and the porous sheet needs to be prepared.

Therefore, an object of the present invention is to provide a chuck table of processing apparatus that allows suppression of the sticking of adhesive tape even when the adhesive layer of the adhesive tape abuts against the chuck table.

In accordance with an aspect of the present invention, there is provided a chuck table of processing apparatus for holding a frame unit in which a wafer is fixed to an opening of a ring-shaped frame with the intermediary of adhesive tape by sucking an exposed surface of the wafer by a holding surface. The chuck table includes a circular region that forms the holding surface in which a plurality of suction holes communicating with a suction source are formed, and a ring-shaped circumferential region that surrounds the circular region. The diameter of the circular region is smaller than the diameter of the wafer. The circumferential region is formed to include the diameter larger than the diameter of the wafer and smaller than the inner diameter of the ring-shaped frame, and a recess that suppresses sticking of the adhesive tape is formed in an upper surface of the circumferential region that gets contact with the adhesive tape.

Preferably, the recess is formed of a ring-shaped recess formed concentrically with the ring-shaped circumferential region. Alternatively, the recess is formed of a plurality of small-diameter recesses having a diameter smaller than the width of the circumferential region.

According to the chuck table of processing apparatus in accordance with the present invention, the holding surface is formed to have a smaller diameter than the wafer and the recess is formed in the ring-shaped region that gets contact with the adhesive tape on the outer circumferential side relative to the holding surface. This can reduce the contact area between an adhesive layer of the adhesive tape and the ring-shaped region of the chuck table and solve the problem of the sticking of the adhesive tape. Furthermore, because a porous sheet is unnecessary, there is also an effect that this leads to significant cost reduction.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of laser processing apparatus;

FIG. 2A is a perspective view of a frame unit in which a wafer is fixed to the opening of a ring-shaped frame with the intermediary of adhesive tape;

FIG. 2B is a sectional view of the adhesive tape;

FIG. 3 is a perspective view of a chuck table of a first embodiment and depicts the relationship between the size of the wafer and the size of a holding surface of the chuck table;

FIG. 4 is a sectional view of the chuck table of the first embodiment;

FIG. 5 is a perspective view of a chuck table of a second embodiment; and

FIG. 6 is a sectional view of the chuck table of the second embodiment.

### DETAILED DESCRIPTION OF THE PREFERRED EMBODIMENTS

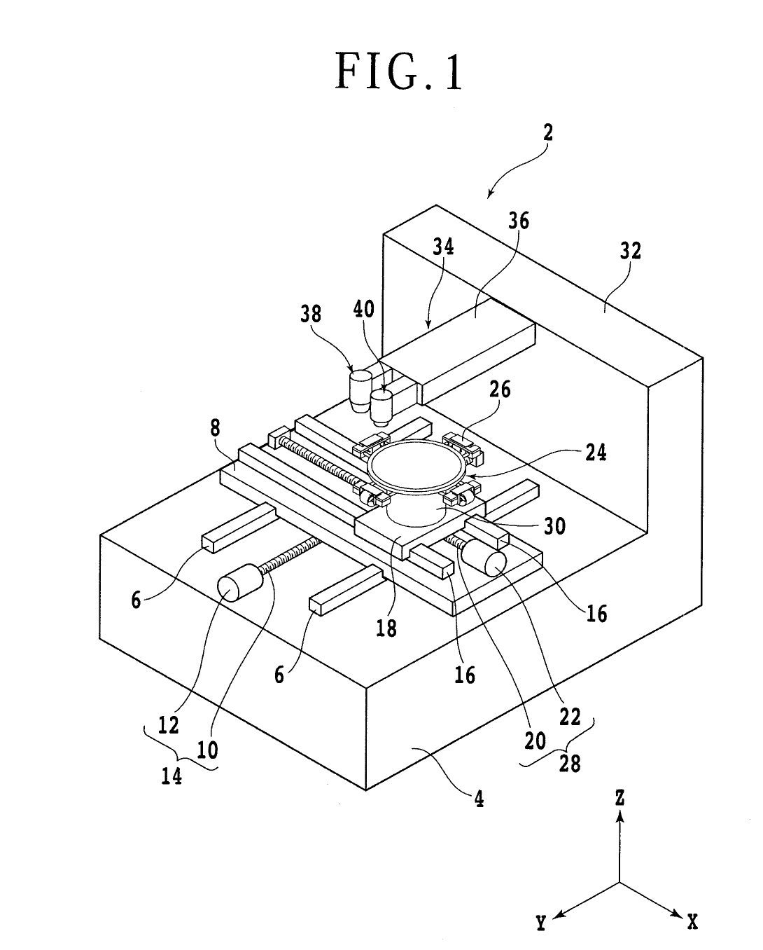

Embodiments of the present invention will be described in detail below with reference to the drawings. FIG. 1 depicts a schematic configuration diagram of a laser processing apparatus 2. The laser processing apparatus 2 includes a pair of guide rails 6 that are mounted on a stationary base 4 and extend along the Y-axis direction. A Y-axis movement block 8 is moved in an indexing feed direction, i.e. the Y-axis direction, by a Y-axis feed mechanism (Y-axis feed means) 14 including a ball screw 10 and a pulse motor 12. On the Y-axis movement block 8, a pair of guide rails 16 extending along the X-axis direction are fixed.

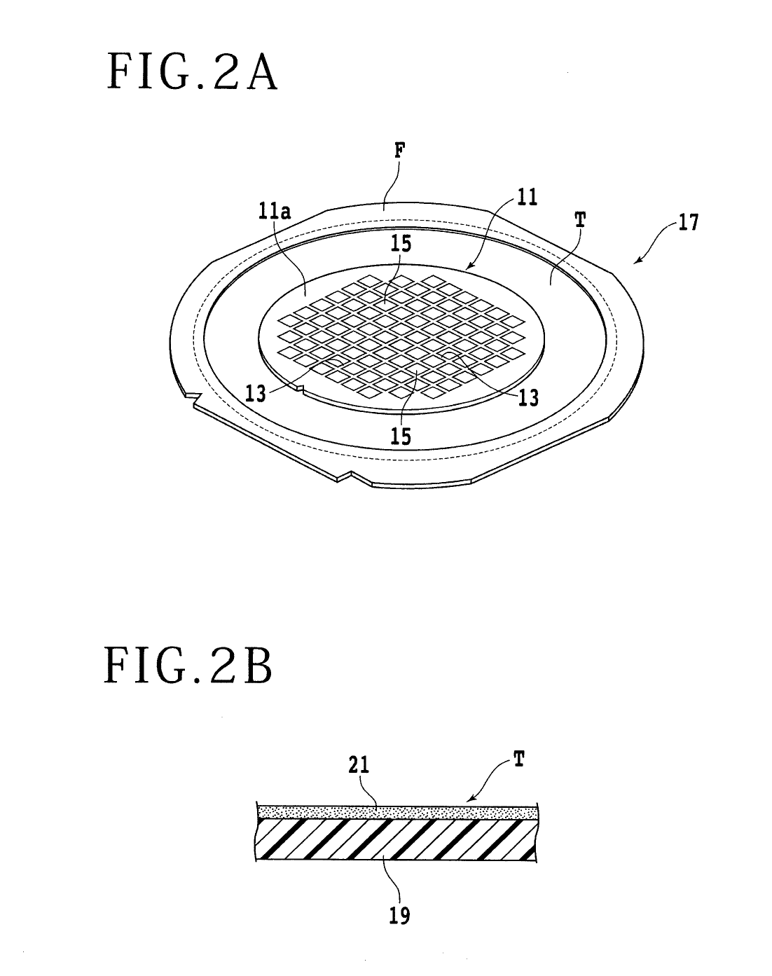

An X-axis movement block 18 is guided by the guide rails 16 and is moved in a processing feed direction, i.e. the X-axis direction, by an X-axis feed mechanism (X-axis feed means) 28 including a ball screw 20 and a pulse motor 22. A chuck table 24 is mounted over the X-axis movement block 18 with the intermediary of a cylindrical support member 30. Around the chuck table 24, plural (four, in the present embodiment) clamps 26 that clamp a ring-shaped frame F depicted in FIG. 2 are disposed.

A column 32 is provided upright on the rear side of the base 4. A casing 36 of a laser beam irradiating unit 34 is fixed to the column 32. Laser beam oscillating means including a YAG laser oscillator or the like is housed in the casing 36, and a light collector (laser head) 38 that focuses a laser beam on a wafer to be processed is mounted to the tip of the casing 36. An imaging unit 40 that images a wafer 11 held by the chuck table 24 is mounted to the tip of the casing 36 of the laser beam irradiating unit 34. The light collector 38 and the imaging unit 40 are disposed to line up in the X-axis direction.

As depicted in FIG. 2A, plural streets 13 are formed in a lattice manner in a front surface 11a of the semiconductor wafer 11 as a processing target of the laser processing apparatus 2. Devices 15 such as ICs and LSIs are formed in each region marked out by the streets 13 at right angles to each other. The wafer 11 is stuck to dicing tape T that is adhesive tape and the circumferential part of the dicing tape T is stuck to the ring-shaped frame F. That is, the wafer 11 is fixed to the opening of the ring-shaped frame F with the intermediary of the adhesive tape (dicing tape) T and a frame unit 17 is formed. As depicted in FIG. 2B, the dicing tape T is formed by applying an adhesive layer 21 on a base 19 including a resin such as polyolefin.

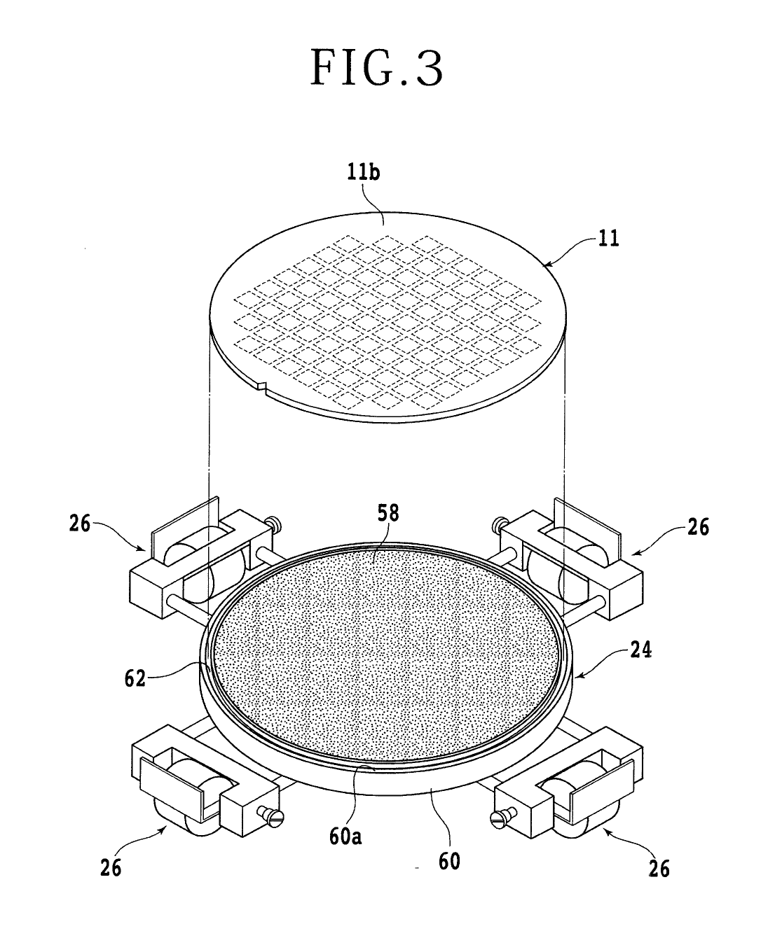

Referring to FIG. 3, a perspective view illustrating the relationship between the size of the wafer 11 and the size of a circular region 58 forming the holding surface of the chuck table 24 in the case in which the wafer 11 is held by the chuck table 24 of a first embodiment of the present invention is depicted. The chuck table 24 has the circular-region holding surface 58 including porous ceramic or the like in which plural suction holes communicating with a suction source are formed. The holding surface 58 is surrounded by a frame body 60 formed of a metal such as SUS. In a ring-shaped upper surface (ring-shaped circumferential region) 60a of the frame body 60 surrounding the holding surface 58 of the circular region, a ring-shaped recess (ring-shaped groove) 62 concentric with the ring-shaped circumferential region 60a is formed.

In FIG. 3, the dicing tape T stuck to a back surface 11b of the wafer 11 and the ring-shaped frame F stuck to the circumference of the dicing tape T are omitted in order to clarify the size relationship between the wafer 11 and the circular holding surface 58. As is apparent from FIG. 3, it is preferable for the circular holding surface 58 to be formed to include the diameter slightly smaller than the diameter of the wafer 11.

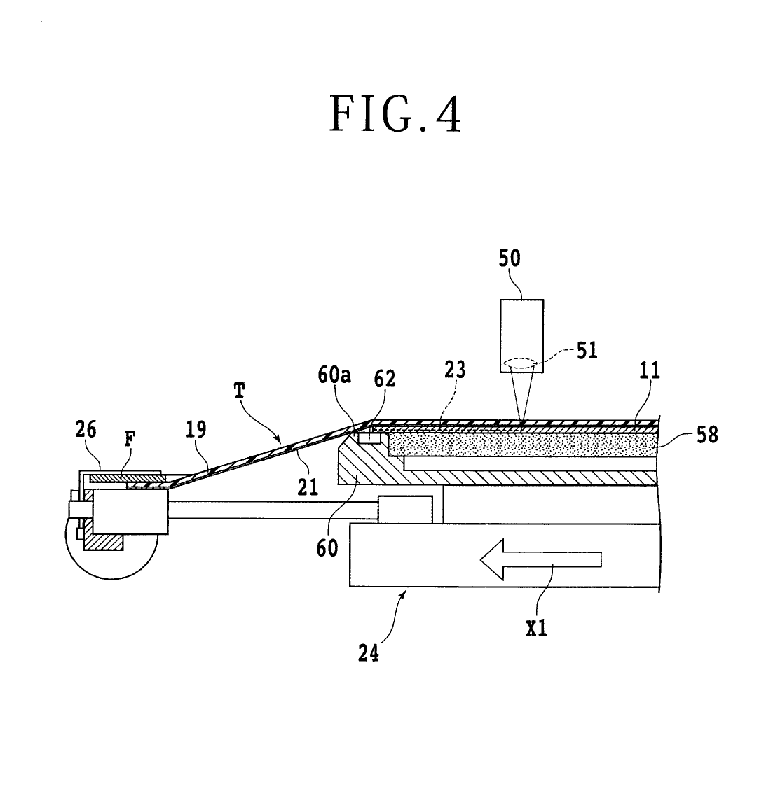

Referring to FIG. 4, a sectional view of the state in which the side of the front surface 11a of the wafer 11 is held by suction by the holding surface 58 of the chuck table 24 of the first embodiment and the ring-shaped frame F is clamped and fixed by the clamps 26 is depicted. The dicing tape T is stuck to the back surface 11b of the wafer 11 and the side of the front surface 11a of the wafer 11 is held by suction by the holding surface 58 of the chuck table 24. Thus, the adhesive layer 21 of the dicing tape T abuts against the ring-shaped circumferential region 60a forming the upper surface of the frame body 60 on the outside of the wafer 11 in the radial direction. However, in the chuck table 24 of the present embodiment, the ring-shaped recess (ring-shaped groove) 62 is formed in the ring-shaped circumferential region 60a. Thus, the sticking of the dicing tape T to the ring-shaped circumferential region 60a is suppressed.

After the wafer 11 is held by the holding surface 58 of the chuck table 24, a modified layer forming step of forming a modified layer inside the wafer 11 is carried out. In this modified layer forming step, the wafer 11 is irradiated, through the dicing tape T, with a laser beam having such a wavelength (e.g. 1064 nm) as to be transmitted through the dicing tape T and the wafer 11 while the light focus point thereof is set inside the wafer 11 by a light collecting lens 51 of a light collector 50, and processing feeding of the chuck table 24 in a direction of an arrow X1 is carried out. Thereby, a modified layer 23 is formed inside the wafer 11 along the planned dividing line 13.

Referring to FIG. 1, with indexing feeding of the chuck table 24 in the Y-axis direction, the modified layers 23 are formed inside the wafer 11 along all planned dividing line 13 extending along a first direction. Subsequently, the chuck table 24 is rotated by 90° and then the modified layers 23 are formed inside the wafer 11 along all planned dividing line 13 extending along a second direction orthogonal to the first direction.

After the end of the modified layer forming step, the clamps 26 are released and the frame unit 17 is separated from the chuck table 24. At this time, because the ring-shaped recess 62 is formed in the ring-shaped circumferential region 60a of the chuck table 24, the sticking of the dicing tape T to the ring-shaped circumferential region 60a is suppressed and the frame unit 17 can be easily separated from the chuck table 24 without causing any damage.

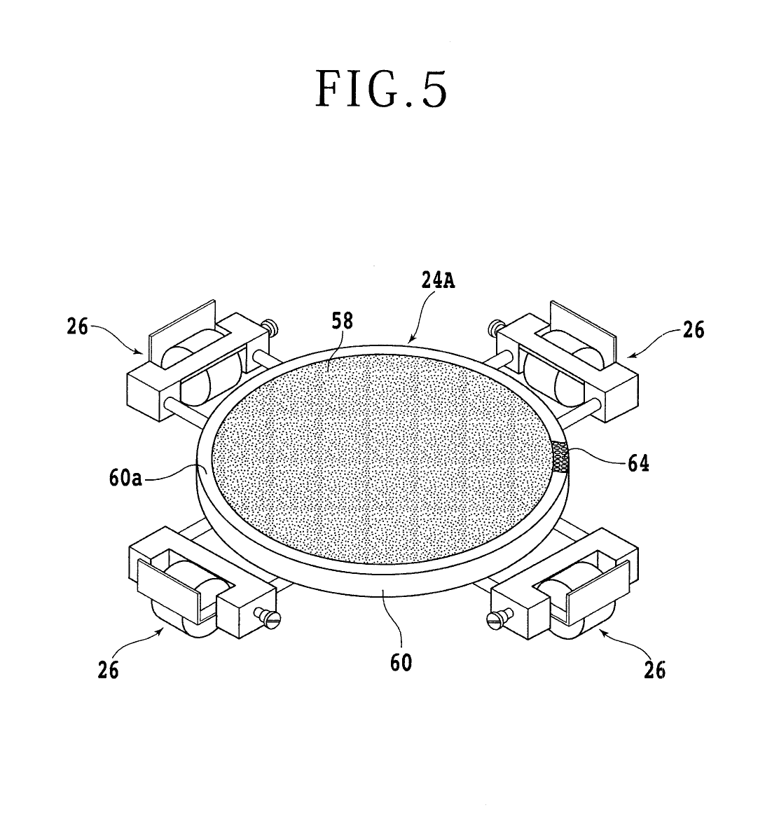

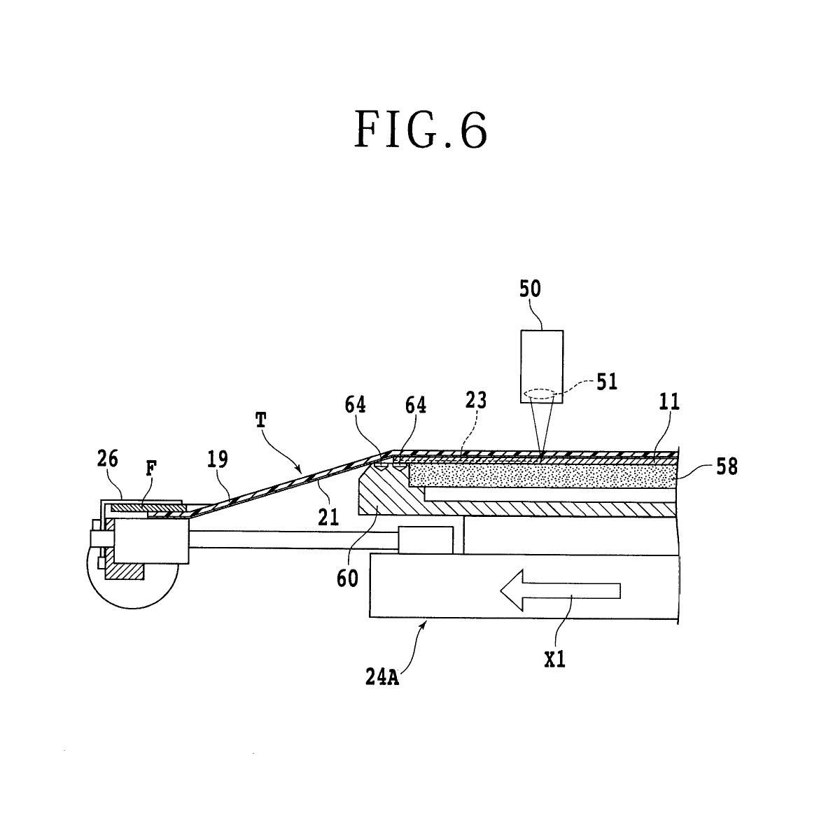

Referring to FIG. 5, a perspective view of a chuck table 24A according to a second embodiment of the present invention is depicted. In the chuck table 24A of the present embodiment, plural small-diameter recesses 64 smaller than the width of the ring-shaped circumferential region 60a of the chuck table 24A are formed in the ring-shaped circumferential region 60a. Because the plural small-diameter recesses 64 are formed in the ring-shaped circumferential region 60a of the chuck table 24A in this manner, the contact between the adhesive layer 21 of the dicing tape T and the ring-shaped circumferential region 60a is suppressed. Therefore, the sticking of the dicing tape T to the ring-shaped circumferential region 60a is suppressed.

Although the plural circular small-diameter recesses 64 are formed in the ring-shaped circumferential region 60a in the present embodiment, the shape of the small-diameter recess does not matter. Furthermore, the size of the small-diameter recesses 64 does not have to be uniform and small-diameter recesses having plural sizes may be formed in the ring-shaped circumferential region 60a. A modified layer forming step with the chuck table 24A of the present embodiment is the same as the modified layer forming step of the above-described first embodiment and therefore description thereof is omitted.

In both chuck tables 24 and 24A of the first and second embodiments, it is more preferable to coat the ring-shaped circumferential region 60a with a resin having high non-adhesiveness, such as Teflon (registered trademark), for prevention of the sticking of the dicing tape T. In the above-described embodiments, the example in which the chuck table of the present invention is employed for laser processing apparatus is described. However, the present invention is not limited thereto and can be applied also to processing apparatuses of the type in which an adhesive layer of adhesive tape gets contact with the circumferential part of the upper surface of a chuck table when processing is carried out.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A chuck table of processing apparatus for holding a frame unit in which a wafer is fixed to an opening of a ring-shaped frame with intermediary of adhesive tape by sucking an exposed surface of the wafer by a holding surface, the chuck table comprising:
a circular region that forms the holding surface in which a plurality of suction holes communicating with a suction source are formed, and
a ring-shaped circumferential region that surrounds the circular region,
wherein
the circular region is smaller than a diameter of the wafer, and
the circumferential region is formed to be larger than the diameter of the wafer and be smaller than an inner diameter of the ring-shaped frame, and a recess that suppresses sticking of the adhesive tape is formed in an upper surface of the circumferential region that gets contact with the adhesive tape.

2. The chuck table of processing apparatus according to claim 1, wherein
the recess is formed of a ring-shaped recess formed concentrically with the ring-shaped circumferential region.

3. The chuck table of processing apparatus according to claim 1, wherein
the recess is formed of a plurality of small-diameter recesses having a diameter smaller than width of the ring-shaped circumferential region, and the plurality of small-diameter recesses are distributed in the upper surface of the circumferential region.
